(19) United States
(12) Patent Application Publication
(10) Pub. No.: US 2004/0250764 A1
(43) Pub. Date: Dec. 16, 2004

(54) Method and apparatus for production of high purity silicon

(76) Inventors: Mitsugu Nagano, Sendai-shi Miyagi (JP); Takehiko Moriya, Sendai-shi Miyagi (JP); Takehiro Takoshima, Hokkaido (JP); Nobuyuki Mori, Furukawa-shi Miyagi (JP); Fumiteru Yamaguchi, Osaka (JP)

Correspondence Address: JORDAN AND HAMBURG LLP, 122 EAST 42ND STREET, SUITE 4000, NEW YORK, NY, 10168, US

(21) Appl. No.: 10/276,668

(22) PCT Filed: May 15, 2001
(86) PCT No.: PCT/JP01/04052

(30) Foreign Application Priority Data
May 16, 2000 (JP) 2000-143752

(51) Int. Cl. C01B 33/02; C23C 16/00

(52) U.S. Cl. 118/715; 423/349

(57) ABSTRACT

High purity silicon usable for production of solar cells is easily produced with high production efficiency. In a rotary chamber (50) made of quartz, which is evacuated and filled with an hydrogen-argon atmosphere containing SiF₄, a plasma area (60) is generated by supplying electric power from a coil (51) to decompose SiF₄ and produce silicon as being fine powder particles. Fine particles of seed silicon (Si) in the rotating reaction chamber are picked up and transported upward by weirs (52), and then they can fall by gravity into the plasma area where silicon elements produced by decomposition of SiF₄ are deposited onto surfaces of the silicon fine particles.

The present invention relates to a method and apparatus for producing high purity silicon.

### BACKGROUND OF THE INVENTION

There is a large demand for high purity silicon as materials for production of semiconductor devices and solar cells. Although siliceous sand (SiO₂) as a raw material of high purity silicon is one of the abundant and the chief elements in the earth crust, it must be highly purified through reducing and purifying processes adopting a high-level and complicated physicochemical technology to obtain high purity silicon usable for production of the semiconductor devices and solar cells. Some drawbacks of such processes are low productivity and high production cost of high purity silicon.

In particular, metal silicon material usable for making solar cells has somewhat lightened purity requirement in comparison with silicon material for semiconductor devices but should have a large light-receiving surface area and hence should be produced at a low cost by mass production technology in connection with rising demand for solar cells most desirable for protecting the earth environments.

Accordingly, a variety of production methods have been proposed and attempted. For example, NEDO (New Energy and Industrial Technology Development Organization (JAPAN)) developed a production method that comprises converting silicon dioxide (starting material) to metal silicon by reduction with carbon at 1800° C., removing phosphorus (P) from the metal silicon by electron beam melting at 2000° C. followed by directional solidification for obtaining a purified ingot, removing boron (B) from the ingot by plasma arc melting at 2500° C. in a quartz crucible followed by further directional solidification for obtaining a high purity silicon ingot of the purity of the order of six nines.

However, this method includes high temperature processes to be conducted at temperature higher than 2000° C., which could not avoid mixture of impurities from the environment, as well as purification processes having low productivity. The method, therefore, could not realize low cost production of high purity silicon.

Conventional silicon purification methods use metal silicon obtained by reducing silica (silicon dioxide) with carbon at high temperatures as starting materials to be purified by the purifying process and hence cannot prevent impurities from mixing in the product in the reduction process with carbon.

Furthermore, the purification method for a metal silicon ingot uses a combination of complicated processes of removing impurities P and B by vaporizing at high temperatures of not lower than 2000° C. and iron (Fe) and other elements by directional solidification, all of which are conducted at high temperatures and unable to improve their productivity and further require protection against mixing-in of impurities from crucibles and chambers accommodating metal silicon ingot at high temperatures. The latter fact may increase the cost of production equipment itself.

### SUMMARY OF THE INVENTION

In consideration of the facts that the conventional purification methods are considerably loaded of removing impurities mixed in metal silicon in the process of reducing the starting silica material and the adopted high temperature purification processes are of low productivity, difficult to prevent impurities from mixing-in the product and expensive to manufacture the production apparatus, the present inventor aims at creation of a new method and apparatus for producing high purity silicon by adopting processes different from the conventional methods. Accordingly, a primary object of the present invention is to provide a new mass-production method which is simple and capable of producing high purity metal silicon at a low cost by using, as starting materials, silicon fluoride not allowing impurities to mixing therein and by obtaining metal silicon directly from the silicon fluoride by applying low-temperature plasma reaction.

The production method for obtaining high purity silicon according to the present invention is featured by generating a plasma in a hydrogen atmosphere containing SiF₄ gas, decomposing SiF₄ in the plasma and at the same time producing silicon as being fine powder particles. By the produced silicon fine particles passing through the plasma, produced silicon is deposited onto surfaces of the silicon fine particles.

The high purity silicon production method according to the present invention, instead of obtaining metal silicon through high-temperature reduction of silicon dioxide with carbon as conducted in the prior art, uses gaseous silicon tetrafluoride obtained through reaction of silica with hydrofluoric acid, which fluoride does not allow the reduction of impurities (transition elements other than silicon) and enables the separation of the impurities in solid state without migrating to the silicon tetrafluoride. The silicon fluoride is gaseous at an ordinary temperature and can be easily purified by using a low-temperature compression method, which has an advantage of achieving a certain high purity before applying it as a starting material for the production process.

According to the present invention, a plasma is generated in a decreased-pressure atmosphere composed of a mixture of silicon tetra fluoride with hydrogen while allowing silicon powder to falling through the plasma, and so-called plasma CVD (chemical vapor deposition) reaction occurs between the atmosphere and silicon powder in such a way that silicon decomposed from the silicon tetra fluoride by the plasma is deposited onto the silicon powder surface and is grown.

As the growth occurs on the surface of silicon powder as being fine particles, a very large entire reaction surface uniformly contacts with the reaction gas in the plasma. This ensures smooth and rapid processing with a very large deposition per unit time.

Thus, the silicon powder can quickly grows and be taken out of the reaction system at a stage of growth to a size suitable for use as starting materials, usable for production of semiconductor.

The method of the present invention can easily obtain high-purity silicon materials having the purity of more than six nines since the material in the form of silicon tetrafluoride may be of high purity and does not allow environmental impurities to mix therein in the process of silicon growth by the plasma CVD method. In addition, as described above, the process can achieve high reaction efficiency and high productivity.

The reaction process uses the plasma CVD reaction in which the reaction gas excited as a plasma has very high activity but the atmosphere in a reaction chamber has a low temperature of about 200° C., thereby the reaction furnace has no need of having specially high heat-resistant structure and the plasma reaction area can be separated at a specified space from the wall surface of the reaction chamber not to allow impurities to mix therein from the surrounding structures.

The reaction process consumes electric energy mainly for generating a plasma and endothermic reaction for decomposing the silicone tetra fluoride. Since this reaction robes the silicon tetra fluoride of fluorine and combines fluorine with hydrogen, the power consumption of the process may be deceased.

On the other hand, hydrogen fluorides produced in the reaction process can be taken out of the reaction system through a closed system during a dry process and reused as starting materials for production of silicon tetrafluorides, realizing the least load to the environment.

Another object of the present invention is to provide a high-purity silicon production apparatus which comprises a rotary reaction chamber of a substantially cylindrical shape with weirs made on its inside wall along the chamber rotation axis, which chamber can be shut off the outside air to control the reaction atmosphere therein and is further provided with a device for supplying gaseous starting material and hydrogen gas, a device for discharging gas produced by reaction, a device for generating a plasma in an area within the reaction chamber and is further provided with, a device for feeding silicon powder into the chamber and a device for taking silicon powder (product) from the chamber, wherein silicon powder supplied into the reaction chamber is carried upward by the weirs with rotation of the reaction chamber and freely falls to pass the plasma area generated with power supply in the reaction chamber so that silicon separated in the plasma may deposit on the surface of silicon powder.

The apparatus can maintain the specified reaction conditions of a plasma reaction area and high reaction efficiency by continuously feeding gaseous starting materials such as silicon tetra fluoride (gas) and hydrogen gas and discharging gaseous reaction products. In the reaction chamber, silicon powder is transported upward by the weirs with rotation of the reaction chamber so that it may freely fall toward the plasma reaction area generated the chamber. Silicon separated in the plasma area can be efficiently deposited directly, without contacting with the chamber wall surface (i.e., without being contaminated with other elements), on the surfaces of the silicon particles falling therein. The weir may be linear, helical, or any other suitable pattern in respect to the rotation axis of the reaction chamber and may have a section suitable for picking up the silicon powder.

In the production apparatus, the plasma is generated in the near center portion of the reaction chamber with the atmosphere maintained under a certain decreased pressure and the silicon crystal powder moves upwards along the chamber wall as the chamber rotates, then freely falls from the top side of the chamber, passes the central plasma area and returns to the bottom of the chamber. Therefore, a high purity silicon layer deposited on surface of each silicon particle becomes thicker by repeatedly passing though the plasma during the rotation of the reaction chamber. When the deposited high purity silicon layer has grown to a specified thickness, the reaction chamber is tilted to discharge the silicon product from the opposite end thereof.

In the apparatus, the reaction rate is determined depending upon a feed rate of hydrogen radicals and hence the reaction efficiency may be further improved by providing a separate system for generating hydrogen radicals.

The hydrogen radical generating system may be such that hydrogen radicals are generated by any of known methods, for example, for effectively ionizing hydrogen gas by glow discharging Ar+H₂ gas or injecting electrons from a hollow cathode electron gun.

### BRIEF DESCRIPTION OF THE DRAWINGS

FIG. 1 is a flow diagram depicting processes of a high-purity silicon production method according to the present invention. FIG. 2 is a cross-sectional view of a reaction chamber of the high-purity silicon production method according to the present invention.

### DETAILED DESCRIPTION OF THE PREFERRED EMBODIMENT

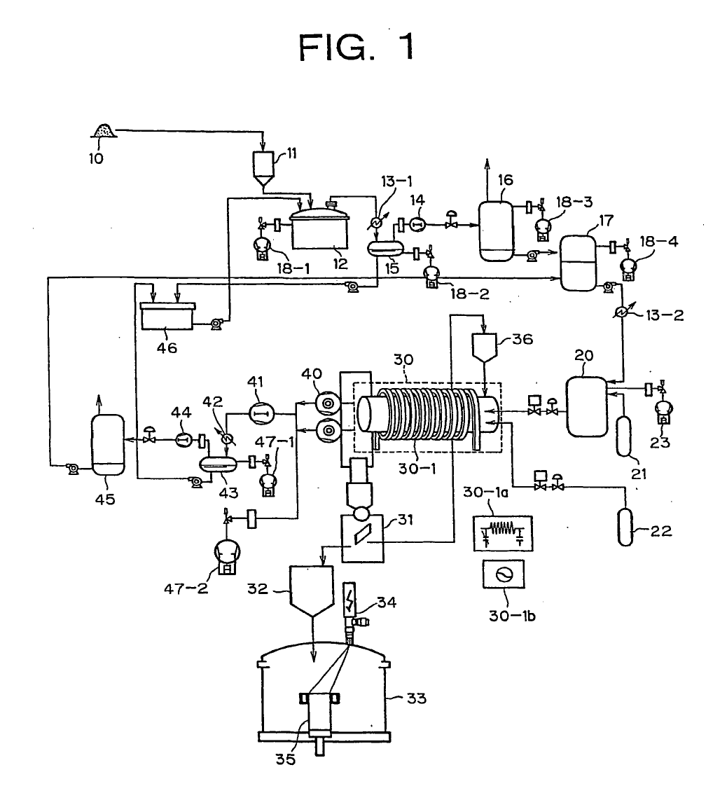

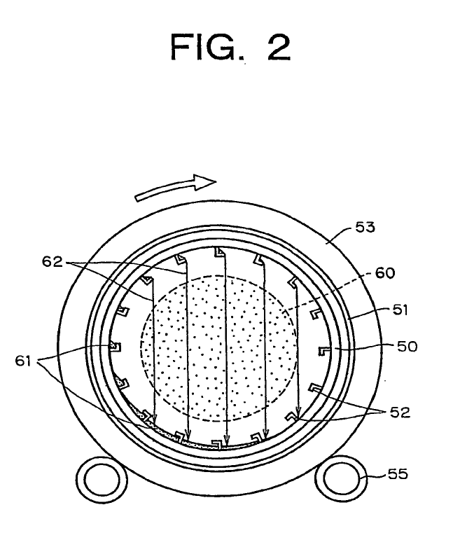

FIG. 1 is a flow diagram of a silicon purifying process of the present invention. In FIG. 1, there is shown a starting material (siliceous sand) 10, a hopper 11, a reaction drum 12, a gas cooler 13-1, an evaporator 13-2, a rotary compressor 14, a tank 15, an expansion tank 16, a surge tank 17, a roughing vacuum pump 18, a pressure control tank 20, a SiF₄ gas bomb 21, a H₂ gas bomb 22, a roughing vacuum pump 23, a plasma reaction device 30, a reactor (reaction chamber) 30-1, fine silicon powder 31, a hopper 32, a vacuum chamber 33, a electron beam generator 34, a polysilicon ingot 35, a turbomolecular pump 40, a Roots pump 41, a gas cooler 42, a tank 43, a rotary compressor 44, an expansion tank 45, a hydrofluoric acid tank 46 and a roughing vacuum pump 47.

In the silicon purification process of the present invention, the starting material (siliceous sand) 10 is loaded from the hopper 11 into the reaction drum 12 in which the silica reacts with hydrogen fluoride to form silicon tetrafluoride (SiF₄ gas). The gasification is prompted by evacuating the reaction drum 12 by using the roughing vacuum pump 18-1. Humidity is removed by using the gas cooler 13-1, the hydrogen fluoride (HF) is liquefied by using the rotary compressor 14 and then the gaseous silicon tetrafluoride is fed to the expansion tank 16 in which the gas is purified from other impurities such as nitrogen gas and then fed and stored in the surge tank 17. In the evaporator 13-2, the gas is heated with hot water to form silicon tetrafluoride gas and fed to the pressure control tank 20 in which it is mixed with silicon tetrafluoride gas fed from the SiF₄ gas bomb 21 until the mixture gas reaches a specified pressure. In the plasma reaction device 30, plasma is applied to the silicon tetrafluoride gas and hydrogen gas to obtain silicon powder by the plasma reaction. In this process, prepared silicon powder 31 which has high crystal quality is fed from the hopper 36, which is used as seed crystals allowing the rapid homoepitaxial growth of a new silicon layer thereon. Thus, silicon crystal material, e.g. silicon powder of excellent crystal quality can be obtained at a high deposition rate. The gas after the reaction is discharged by the turbomolecular pump 40 and fed through the Roots pump 41 to the gas cooler in which hydrogen fluoride (HF) is liquefied and recovered. The gas is then compressed by the rotary compressor 44 to obtain liquefied tetrafluoride that is then expanded in the expansion tank 45 to separate H₂ gas by vaporization and obtain high purity silicon tetrafluoride (liquid). The liquefied silicon tetrafluoride stored in the expansion tank 45 is fed through a high-pressure line to the surge tank 17 and then reused.

Silicon powder 31 obtained by the present process is loaded from the hopper 32 into the electron-beam melting device (consisting of the vacuum chamber 33 and the electron beam generator 34) by which a high-purity silicon ingot 35 can be obtained.

FIG. 2 is a schematic cross-sectional view of a reaction chamber (corresponding to the reaction camber 30-1 as shown in FIG. 1) according to the present invention.

In FIG. 2, there is shown a reaction chamber 50, a coil 51, weirs 52 and a rotation support ring 53. The reaction chamber is driven into rotation by supporting rollers 55. Although an induction type plasma generator is used in the shown embodiment, a capacitor type plasma generator composed of externally disposed electrodes may be also used if the chamber has an enough space therein.

In the reaction chamber 50, high-frequency power from the coil 51 is applied to generate a plasma area 60 in a substantially center portion of a decreased-pressure atmosphere of silicon tetrafluoride gas and hydrogen gas. As shown in FIG. 2, the plasma area is formed in the substantially center portion at a space separated from the wall surface of the reaction chamber. The plasma area is heated by plasma generation heat to a temperature of 200° C. to 400° C.

In this area, the starting gaseous material (silicon tetrafluoride) reacts with hydrogen to dissociate silicon according to the following reaction.

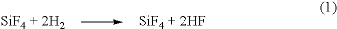

This reaction is endothermic but the atmosphere temperature can be maintained at 200° C. to 400° C. by heat generated by the plasma.

During rotation of the reaction chamber, silicon crystal powder 61 loaded into the reaction chamber through one end thereof is pickup by weirs 52 formed on the chamber inner wall and carried to the top position of respective weirs, from which it falls by gravity as shown at 62 and passes the plasma area 60 while dissociated silicon deposits by epitaxy onto the surface of the falling silicon powder. Although a typical weir shape is illustrated, it may be modified to any convex shape suitable for picking up silicon powder.

The atmosphere temperature is relatively low, i.e., its plasma area has a relatively low temperature plasma. However, since very active radicals may be produced in the atmosphere in the state exited by the plasma, the reaction rapidly proceeds and silicon crystal layer effectively deposits and grows on the surface of silicon powder freely falling in the plasma by the well-known effect of the homoepitaxial CVD reaction as adopted for producing semiconductor devices.

This reaction process can be conducted under the conditions of: RF frequency of 13.56 MHz, input power of 4 KW, gas pressure of 0.1-30 Torr and starting-gas flow rate 0.1-1/min (SiF₄) and 0.1-2 1/min (H₂).

In the reaction process, silicon crystal particles freely fall, being uniformly dispersed over the plasma area, thereby silicon produced according to the reaction (1) is evenly swept attaining a high productivity.

The weir system 52 acting as the above-described silicon crystal powder spreading mechanism may be arranged linearly along the rotary axis of the chamber. Alternatively, weirs may be formed helically and the cross-sectional shape of the weir system 52 may be varied and adjusted to smoothly vary the dispersion of silicon powder.

Practical reaction conditions are as follows:

The reaction process can be implemented at a RF frequency of 13.56 MHz, input electric power of 4 KW, gas pressure of 0.1 to 30 Torr, starting-gas flow rates of 0.1 to 1/min (SiF₄) and 0.1 to 2/min (H₂).

The seed crystal acting as a nucleus for growing the new crystal thereon was obtained by this process. The depositing rate of fine silicon crystal powder in the process was in the rage of 0.5 to 5 g/h.

Since the present invention does not aim at obtaining a planar polycrystalline layer, fine crystal particles irregularly formed depending upon actual reaction conditions or fine crystal particles separated after production may be allowed and thus deposited particles formed by such way may be also used as seed crystal particles.

Silicon wafer crushed to fine particles may be also used as seed crystal powder.

The production of silicon and the silicon-forming rate of this reaction is determined depending upon the feed rate of atomic hydrogen or hydrogen radicals. Therefore, when a constant feed rate of SiF₄ gas is preset for forming a silicon crystal on the surface of each silicon particle, the decomposition rate may be determined in accord with a feed rate of hydrogen radicals.

To further improve the production efficiency of the production apparatus, the following method may be adopted to effectively generate hydrogen radicals.

(1) In addition to the existing reaction chamber, a separate reaction chamber is provided for generating hydrogen radicals to be effectively fed to the main reaction chamber.

(2) As widely adopted in the semiconductor manufacturing processes, a hot wire cell method may be used for generating hydrogen radicals by heating a metal filament catalyst (W, Mo, Si) to a temperature of 1500° C. to 2000° C.

(3) Electrons are injected into the plasma by using a neutralizer or a hollow cathode to effectively generate hydrogen radicals.

In the above description, SiF₄ is decomposed with hydrogen radicals by using the low gas pressure and low-temperature plasma to produce silicon powder. It was confirmed that the silicon crystal powder could be obtained under the condition that gas pressure is made to be higher. It was understood that since the increasing of gas pressure leads to high temperature, it becomes high temperature of SiF₄ and the decomposition of SiF₄ is accelerated.

For example, the process can be implemented under the following conditions:

Gas pressure: 100-1000 Torr

Electric energy: 10-50 KW

Gas components and flow rates:

| | |
|---|---|
| SiF₄ | 0.1-10 m³/min. |
| Ar | 50-100 m³/min. |
| H₂ | 0.1-10 m³/min. |

The growing mechanism is determined depending upon the feed rate of SiF₄ gas. On the other hand, the deposition rate is 0.3 g/sec at electric energy of 10KW and a SiF₄ feed rate of 0.1 m³/min and it is 5 g/sec at the same electric energy and a SiF₄ feed rate of 1 m³/min.

As be apparent from the foregoing, the high-purity silicon production can be achieved at low cost by using SiF₄ gas as the starting material, which is obtained from siliceous sand as one of the well-known materials.

1. A high purity silicon production method comprising:
generating plasma in a hydrogen atmosphere containing SiF₄ gas;
decomposing SiF₄ in the plasma; and
passing silicon fine material produced by decomposition through the plasma, wherein silicon produced by decomposition of the SiF₄ is deposited on the silicon crystal material surface.

2. A high purity silicon production apparatus comprising:
a rotary reaction chamber having a substantially cylindrical shape and weirs formed on its inside wall along a rotation axis of the rotary reaction chamber;
a device for controlling a reaction atmosphere by shutting off the rotary reaction chamber from the outside air;
a device for supplying starting material gas;
a device for supplying hydrogen gas;
a device for discharging reaction product gas;
a device for generating a plasma in an inside area of the reaction chamber;
a device for feeding silicon material to the reaction chamber; and
a device for discharging silicon material from the reaction chamber;
wherein during rotation of the reaction chamber, the silicon material moves upwards by the weirs and freely falls and passes the plasma area generated with power supply in the reaction chamber to deposit silicon decomposed in the plasma onto the silicon crystal material surface.

3. A high-purity silicon production method comprising:
generating plasma in a hydrogen atmosphere containing SiF₄ gas;
decomposing SiF₄ in the plasma to produce silicon; and
passing silicon crystal material serving as seed crystal through the plasma,
wherein silicon produced by decomposition of the SiF₄ is deposited on the silicon crystal material surface.
